(19) United States
(12) Patent Application Publication
(10) Pub. No.: US 2026/0096324 A1
(43) Pub. Date: Apr. 2, 2026

(54) DISPLAY PANEL AND DISPLAY APPARATUS

(71) Applicant: Wuhan Tianma Microelectronics Co., Ltd., Wuhan (CN)

(72) Inventor: Fei Li, Wuhan (CN)

(73) Assignee: Wuhan Tianma Microelectronics Co., Ltd., Wuhan (CN)

(21) Appl. No.: 19/411,811

(22) Filed: Dec. 8, 2025

(30) Foreign Application Priority Data
Sep. 12, 2025 (CN) 202511309692.2

(51) Int. Cl. H10K 59/35; G09G 3/3233; H10K 59/121; H10K 59/131

(52) U.S. Cl. CPC H10K 59/353; G09G 3/3233; H10K 59/1213; H10K 59/131; G09G 2300/0426; G09G 2300/0452; G09G 2300/0465; G09G 2300/0842; G09G 2300/0861; G09G 2330/021

(57) ABSTRACT

Provided are a display panel and a display apparatus. The display panel includes: sub-pixels; light-transmitting areas; signal lines; and pixel circuits. The light-transmitting areas do not overlap with the signal lines and pixel circuits in a direction perpendicular to a plane of the display panel. For a first display column and a second display column arranged along a second direction in the display panel, the first display column includes first color sub-pixels sequentially arranged along a first direction, the second display column includes pixel units sequentially arranged along the first direction. A pixel unit includes a second color sub-pixel and a third color sub-pixel arranged along the first direction. Along the second direction, the pixel units overlap with the first color sub-pixels. A light-transmitting area is located between adjacent first color sub-pixels along the first direction and/or between adjacent second color sub-pixel and third color sub-pixel along the first direction.

### CROSS-REFERENCE TO RELATED APPLICATION

The present application claims priority to Chinese Patent Application No. 202511309692.2, filed on Sep. 12, 2025, the content of which is incorporated herein by reference in its entirety.

### TECHNICAL FIELD

The present application relates to the field of display technologies, and in particular, to a display panel and a display apparatus.

### BACKGROUND

With the development of display technologies, display apparatuses integrate more and more functions. Among them, optical sensors may be integrated into display apparatuses to realize functions such as imaging and biometric identification. To pursue better display effects, the light-transmitting regions of transmissive optical sensors and sub-pixel regions are interspersed with each other. At this time, how to ensure the light transmittance of the light-transmitting regions and the normal light emission of a display panel is a challenge.

### SUMMARY

The present application provides a display panel and a display apparatus to address these and related challenges.

In a first aspect, an embodiment of the present application provides a display panel including: a plurality of sub-pixels; a plurality of light-transmitting areas; a plurality of signal lines; and a plurality of pixel circuits, where the light-transmitting areas do not overlap with the signal lines and the pixel circuits in a direction perpendicular to a plane of the display panel; the display panel further includes a first display column and a second display column arranged along a second direction, the first display column includes first color sub-pixels sequentially arranged along a first direction, the second display column includes pixel units sequentially arranged along the first direction, and a respective pixel unit includes a second color sub-pixel and a third color sub-pixel arranged along the first direction; along the second direction, the pixel units overlap with the first color sub-pixels; and the second direction intersects the first direction; and a respective light-transmitting area is located between adjacent first color sub-pixels along the first direction and/or a respective light-transmitting area is located between adjacent second color sub-pixel and third color sub-pixel along the first direction.

In a second aspect, an embodiment of the present application provides a display apparatus including the display panel as provided in the first aspect.

According to the technical solutions provided by the embodiments of the present application, the light-transmitting area of the light-transmitting areas can be increased under the condition that the areas between the sub-pixels are limited, thereby enabling the light-transmitting areas to have high light transmittance.

### BRIEF DESCRIPTION OF DRAWINGS

To more clearly illustrate the technical solutions of the embodiments of the present application, the accompanying drawings of the embodiments will be briefly introduced below. The accompanying drawings in the following description are merely some embodiments of the present application, and for those of ordinary skill in the art, other accompanying drawings can also be obtained based on these drawings without creative efforts.

FIG. 1 is a schematic diagram of a display panel according to an embodiment of the present application;

FIG. 2 is a schematic diagram of a display panel according to an embodiment of the present application;

FIG. 3 is a schematic diagram of a display panel according to an embodiment of the present application;

FIG. 4 is an equivalent circuit diagram of a pixel circuit related to an embodiment of the present application;

FIG. 5 is a schematic diagram of a partial layout of a display panel according to an embodiment of the present application;

FIG. 6 is a partial structural schematic diagram of a display panel according to an embodiment of the present application;

FIG. 7 is a partial structural schematic diagram of a display panel according to an embodiment of the present application;

FIG. 8 is a partial structural schematic diagram of a display panel according to an embodiment of the present application;

FIG. 9 is a partial structural schematic diagram of a display panel according to an embodiment of the present application;

FIG. 10 is a partial structural schematic diagram of a display panel according to an embodiment of the present application;

FIG. 11 is a partial structural schematic diagram of a display panel according to an embodiment of the present application;

FIG. 12 is a partial structural schematic diagram of a display panel according to an embodiment of the present application;

FIG. 13 is a partial structural schematic diagram of a display panel according to an embodiment of the present application;

FIG. 14 is a partial structural schematic diagram of a display panel according to an embodiment of the present application;

FIG. 15 is a partial structural schematic diagram of a display panel according to an embodiment of the present application;

FIG. 16 is a partial structural schematic diagram of a display panel according to an embodiment of the present application;

FIG. 17 is a schematic diagram of a display apparatus according to an embodiment of the present application.

### DESCRIPTION OF EMBODIMENTS

For a better understanding of the technical solutions of the present application, the embodiments of the present application are described in detail below with reference to the accompanying drawings.

It will be understood that the described embodiments are only a part of the embodiments of the present application, rather than all the embodiments. Based on the embodiments in the present application, all other embodiments obtained by a person of ordinary skill in the art without creative efforts, including new embodiments obtained by combining the various embodiments of the present application on the premise that there is no technical conflict, fall within the protection scope of the present application.

The terms used in the embodiments of the present application are merely for the purpose of describing specific embodiments, rather than intended to limit the present application. The singular forms “a/an” and “the” used in the embodiments of the present application and the appended claims are also intended to include the plural forms, unless the context clearly indicates otherwise.

It should be understood that the term “and/or” used herein merely describes an association relationship of associated objects, indicating that there may be three types of relationships. For example, A and/or B may mean: A exists alone, A and B exist simultaneously, or B exists alone. In addition, the character “/” herein generally indicates that the associated objects before and after it are in an “or”relationship.

In the description of this specification, it should be understood that such terms as “basically”, “approximately”, “about”, “roughly” and “generally” described in the claims and embodiments of the present application refer to values that can be generally recognized within a reasonable process operation range or tolerance range, rather than an exact value.

It should be understood that although terms such as first and second may be used to describe regions and the like in the embodiments of the present application, they should not be limited to these terms. These terms are only used to distinguish regions and the like from each other. For example, without departing from the scope of the embodiments of the present application, a first region may also be referred to as a second region, and similarly, a second region may also be referred to as a first region. Through detailed and in-depth research, the applicant of the present application has provided a solution for the problems existing in the prior art.

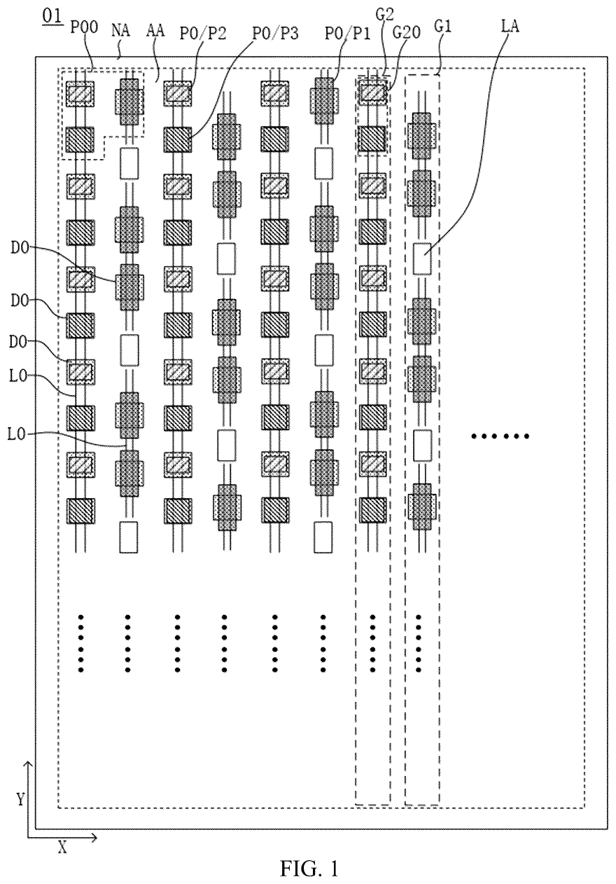

FIG. 1 is a schematic diagram of a display panel according to an embodiment of the present application. As shown in FIG. 1, the display panel 01 according to the embodiment of the present application includes a first display column G1 and a second display column G2, the first display column G1 and the second display column G2 each include sub-pixels P0 sequentially arranged along a first direction Y, and the first display column G1 and the second display column G2 are arranged along a second direction X. Referring to FIG. 1, the first display column G1 includes first color sub-pixels P1 sequentially arranged along the first direction Y, and the second display column G2 includes second color sub-pixels P2 and third color sub-pixels P3 sequentially arranged along the first direction Y. Specifically, the second display column G2 includes pixel units G20 sequentially arranged along the first direction Y, and a respective pixel unit G20 in the second display column G2 includes a second color sub-pixel P2 and a third color sub-pixel P3 arranged along the first direction Y. Along the second direction X, the pixel units G20 each including the second color sub-pixel P2 and the third color sub-pixel P3 overlap with the first color sub-pixels P1. For example, if the first color sub-pixel P1 is a blue sub-pixel, the second color sub-pixel P2 is a red sub-pixel, and the third color sub-pixel P3 is a green sub-pixel, then the first display column G1 included in the display panel 01 according to the embodiment of the present application includes blue sub-pixels sequentially arranged along the first direction Y, the second display column G2 includes a plurality of red sub-pixels and a plurality of green sub-pixels, and one red sub-pixel and one green sub-pixel adjacently arranged along the first direction Y can be regarded as the pixel unit G20, where the pixel unit G20 including the red sub-pixel and the green sub-pixel overlaps with the blue sub-pixel in the second direction X. The arrangement of the sub-pixels P0 in the display panel 01 according to the embodiment of the present application makes the first color sub-pixel P1, the second color sub-pixel P2, and the third color sub-pixel P3 included in a same pixel P00 more compact, makes the color expression of the pixel more excellent, the picture display effect more excellent, and the panel power consumption lower.

With continued reference to FIG. 1, the display panel 01 includes a plurality of sub-pixels P0 and a plurality of light-transmitting areas LA, the sub-pixel P0 is a minimum light-emitting unit in the display panel 01, and the light-transmitting area LA is an area capable of transmitting external light. An optical sensor may be provided below the light-transmitting area LA of the display panel 01, for example, at least one of a camera, a facial recognition sensor, a fingerprint recognition sensor, or the like may be provided below the light-transmitting area LA, such that light received and/or emitted by the optical sensor may propagate through the light-transmitting area LA. The plurality of light-transmitting areas LA can be uniformly distributed over the entire surface within a display area AA of the display panel 01, and the plurality of light-transmitting areas LA may also be concentrated in one area of the display panel 01. The embodiment according to the present application may be applicable to the scenario where the light-transmitting areas LA are uniformly distributed in the display area AA of the display panel 01, or may also be applicable to the scenario where the light-transmitting areas LA are located in one area of the display panel 01. In addition, the display panel 01 may further include a non-display area NA located outside the display area AA.

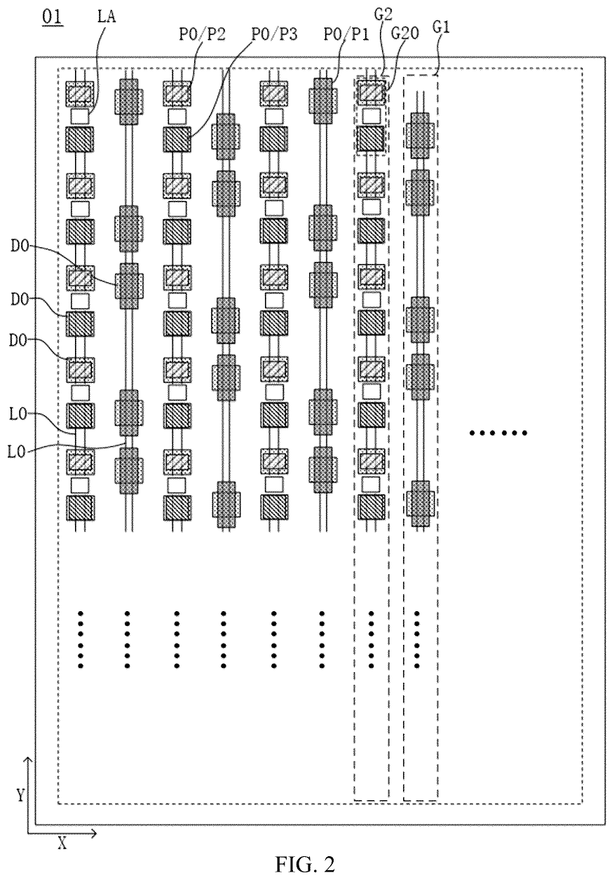

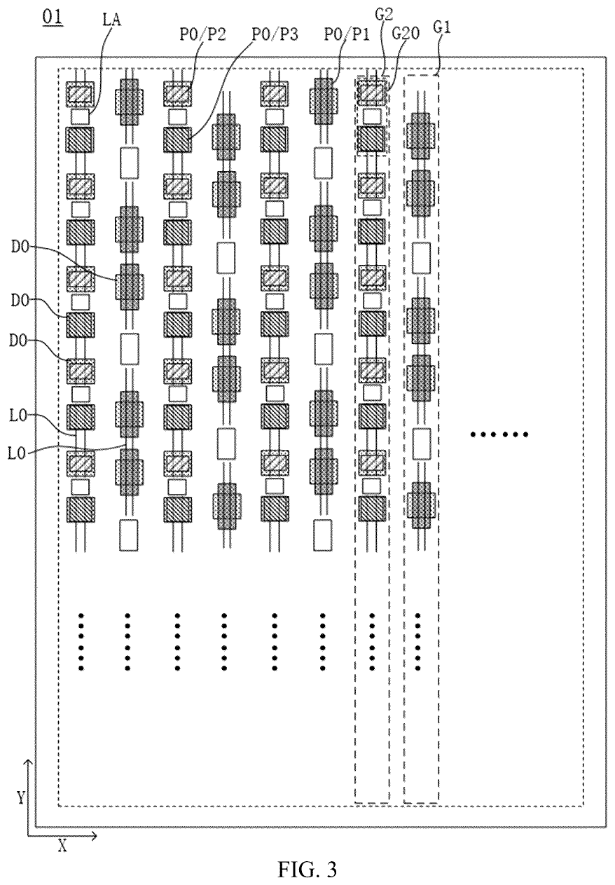

FIG. 2 is a schematic diagram of a display panel according to an embodiment of the present application, and FIG. 3 is a schematic diagram of a display panel according to an embodiment of the present application.

A respective light-transmitting area LA is located between adjacent sub-pixels P0 arranged along the first direction Y, and the light-transmitting area LA may be located between adjacent first color sub-pixels P1 along the first direction Y and/or the light-transmitting area LA may be located between adjacent second color sub-pixel P2 and third color sub-pixel P3 along the second direction X. That is, as shown in FIG. 1, the light-transmitting area LA may be located between adjacent sub-pixels P0 arranged in the first display column G1, or as shown in FIG. 2, the light-transmitting area LA may also be located between adjacent sub-pixels P0 arranged in the second display column G2, or as shown in FIG. 3, a part of the light-transmitting areas LA may be located between adjacent sub-pixels P0 in the first display column G1 and another part of the light-transmitting areas LA may be located between adjacent sub-pixels P0 in the second display column G2. Herein, when the second display column G2 includes a light-transmitting area LA, the light-transmitting area LA in the second display column G2 may be located between adjacent pixel units G20 arranged along the first direction Y, instead of being located between the sub-pixels P0 of the pixel units G20, thereby avoiding the light-transmitting area LA affecting the distance between different sub-pixels P0 in a same pixel, to ensure compact arrangement of the sub-pixels P0 in the same pixel.

As shown in FIG. 1 to FIG. 3, the display panel 01 includes a plurality of signal lines L0 and a plurality of pixel circuits D0. Each sub-pixel P0 includes a light-emitting device; for example, it may include one of an organic light-emitting diode (OLED), a micro-LED, a mini-LED, or the like. The pixel circuit D0 may be configured to drive the light-emitting device to emit light; for example, the pixel circuit D0 may provide a light-emitting driving current for the light-emitting device. At least a part of the signal lines L0 may be electrically connected to the pixel circuits D0 and provide corresponding signals to the pixel circuits D0, and at least a part of the signal lines L0 may also be electrically connected to the light-emitting devices and provide corresponding signals to the light-emitting devices. In the embodiment of the present application, the light-transmitting areas LA do not overlap with the signal lines L0 and the pixel circuits D0 in a direction perpendicular to a plane of the display panel 01, that is, the pixel circuits D0 and the signal lines L0 are designed to avoid the light-transmitting areas LA, so as to ensure that the light-transmitting areas LA of the display panel 01 have high light transmittance.

In an embodiment of the present application, a single pixel P00 includes at least sub-pixels P0 of three colors and the three sub-pixels P0 are arranged in a layout similar to the Chinese character “ [symbol] ”. The arrangement of the sub-pixels P0 in the pixel P00 is more compact, which is conducive to improving the resolution of the display panel 01 and making the display effect of the display panel 01 more delicate. However, the compact arrangement of the sub-pixels P0 reduces the space available for arranging the light-transmitting areas LA, thereby resulting in a smaller area of the light-transmitting areas LA. The technical solution provided by the embodiment of the present application can increase the light-transmitting area of the light-transmitting areas LA under the condition that the areas between the sub-pixels P0 are limited, thereby enabling the light-transmitting areas LA to have high light transmittance.

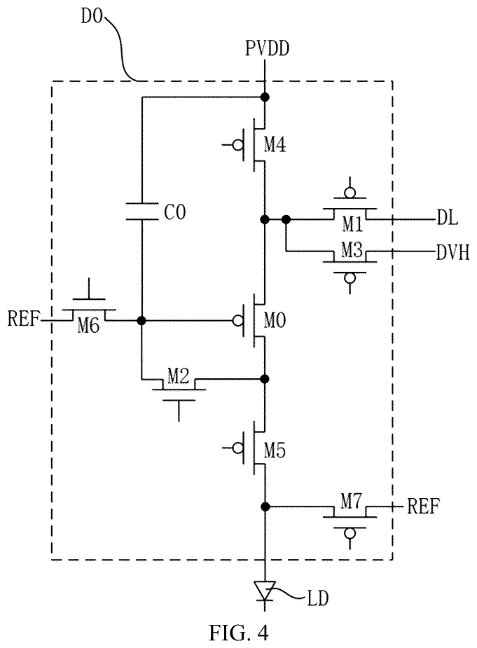

FIG. 4 is an equivalent circuit diagram of a pixel circuit related to an embodiment of the present application.

As shown in FIG. 4, the pixel circuit D0 includes a driving transistor M0, a data writing transistor M1, a threshold extraction transistor M2, a bias transistor M3, a power supply voltage writing transistor M4, a light emission control transistor M5, a first reset transistor M6, a second reset transistor M7, and a storage capacitor C0. A source of the data writing transistor M1 is electrically connected to the data line DL, and a drain of the data writing transistor M1 is electrically connected to a source of the driving transistor M0. A source of the threshold extraction transistor M2 is electrically connected to a drain of the driving transistor M0, and a drain of the threshold extraction transistor M2 is electrically connected to a gate of the driving transistor M0. The storage capacitor C0 is electrically connected to the gate of the driving transistor M0. When the data writing transistor M1 and the threshold extraction transistor M2 are turned on, a data voltage transmitted on the data line DL can be written to the gate of the driving transistor M0, and the storage capacitor C0 can maintain a potential at the gate of the driving transistor M0 at a potential corresponding to the data voltage. A source of the bias transistor M3 is electrically connected to a bias signal line DVH, and a drain of the bias transistor M3 is electrically connected to the source of the driving transistor M0. When the bias transistor M3 is turned on, a bias voltage transmitted by the bias signal line DVH can be transmitted to the driving transistor M0 to bias the driving transistor M0. A source of the power supply voltage writing transistor M4 is electrically connected to a power supply voltage line PVDD, and a drain of the power supply voltage writing transistor M4 is electrically connected to the source of the driving transistor M0. A source of the light emission control transistor M5 is electrically connected to the drain of the driving transistor M0, and a drain of the light emission control transistor M5 is electrically connected to a light-emitting device LD. When the power supply voltage writing transistor M4 and the light emission control transistor M5 are turned on, a power supply voltage transmitted by the power supply voltage line PVDD can be written to the driving transistor M0, and the driving transistor M0 is controlled to output a corresponding driving current to the light-emitting device LD based on the data voltage and the power supply voltage. A source of the first reset transistor M6 is electrically connected to a reset signal line REF, and a drain of the first reset transistor M6 is electrically connected to the gate of the driving transistor M0. A source of the second reset transistor M7 is electrically connected to the reset signal line REF, and a drain of the second reset transistor M7 is electrically connected to the light-emitting device LD. When the first reset transistor M6 is turned on, the reset voltage transmitted by the reset signal line REF can be transmitted to the gate of the driving transistor M0; and when the second reset transistor M7 is turned on, the reset voltage transmitted by the reset signal line REF can be transmitted to the light-emitting device LD.

It should be noted that FIG. 4 merely illustrates a pixel circuit D0 related to the embodiment of the present application, and the pixel circuit D0 corresponding to the embodiment of the present application may also be a pixel circuit D0 in another form, which is not limited in the present application.

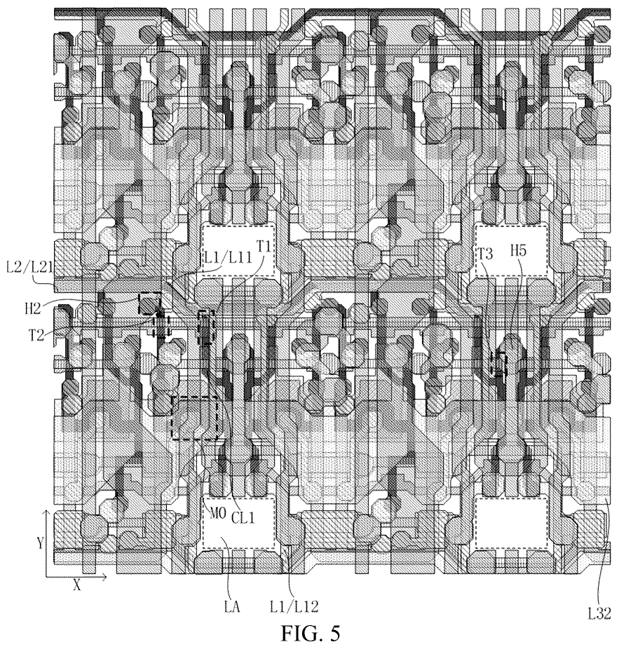

FIG. 5 is a schematic diagram of a partial layout of a display panel according to an embodiment of the present application.

In an embodiment of the present application, as shown in FIG. 5, the pixel circuit D0 includes a first transistor T1, the light-transmitting area LA is located on a side of the first transistor T1 in the first direction Y, and the light-transmitting area LA overlaps with and is adjacent to the first transistor T1 in at least a part of the pixel circuits D0 in the first direction Y. With respective to the light-transmitting area LA and the pixel circuit D0 that are close to each other in the first direction Y, the first transistor T1 may be one of the transistors in the pixel circuit D0 where it is located that is adjacent to or closest to the light-transmitting area LA in the first direction Y. For the convenience of description, the first transistor T1 and the light-transmitting area LA are hereinafter referred to as the adjacent first transistor T1 and light-transmitting area LA. It should be noted that a signal line L0 or the like may be provided between the adjacent first transistor T1 and light-transmitting area LA, and the first transistor T1 here refers to a transistor closer to the light-transmitting area LA than other transistors in the pixel circuit D0. Herein, a first electrode of the first transistor T1 is electrically connected to the first signal line L1, and when the first transistor T1 is turned on, a signal transmitted on the first signal line L1 can be written to a corresponding node.

The first signal line L1 includes a first signal sub-line L11 extending along the second direction X, the first signal sub-line L11 is connected to first electrodes of a plurality of first transistors T1 arranged along the second direction X, and the second direction X intersects the first direction Y. That is, the first signal sub-line L11 is electrically connected to the plurality of first transistors T1 in its extending direction, and the extending direction of the first signal sub-line L11 intersects the arrangement direction of the adjacent first transistor T1 and light-transmitting area LA. It should be noted that the first signal sub-line L11 is not necessarily a straight-line structure, for example, as shown in FIG. 5, the first signal sub-line L11 is a polyline structure, and the first signal sub-line L11 extending along the second direction X refers to that the extending direction of the first signal sub-line L11 is substantially the second direction X, that is, the overall extending direction of the first signal sub-line L11 is the second direction X. If the first signal sub-line L11 is electrically connected to the first transistor T1 through a via hole, then with respect to the adjacent first transistor T1 and light-transmitting area LA, the via hole used when the first transistor T1 is electrically connected to the first signal sub-line L11 will affect the light-transmitting area of the light-transmitting area LA.

In an embodiment of the present application, the first signal sub-line L11 and the first electrode of the first transistor T1 are located in a same semiconductor layer and are formed as an integral structure, and therefore, the first signal sub-line L11 and the first electrode of the first transistor T1 electrically connected thereto are respectively different parts interconnected in the same semiconductor layer. By arranging the first signal sub-line L11 in the same semiconductor layer as the first electrode of the first transistor T1 to realize an electrical connection between the two, the electrical connection between the first signal sub-line L11 and the first transistor T1 can be implemented without using a via hole, thereby avoiding the light-transmitting area of the light-transmitting area LA being affected by such via holes.

In an embodiment of the present application, the pixel circuit D0 further includes a driving transistor M0, a second electrode of the first transistor T1 is electrically connected to the driving transistor M0, and the first transistor T1 is configured to control the transmission of a bias voltage transmitted on the first signal line L1 to the driving transistor M0. Then, the first transistor T1 may be the bias transistor M3, and the first signal line L1 may be the bias signal line DVH. Therefore, a first connection structure is configured to transmit the bias voltage to a first electrode of the driving transistor M0 for biasing the driving transistor M0. Since the bias voltage is usually a voltage with a fixed potential, even if the first signal sub-line L11 in the first signal line L1 is located in the semiconductor layer, this ensures that the bias voltage is effectively transmitted to the first transistor T1, thereby effectively biasing the driving transistor M0 when the first transistor T1 is turned on.

Herein, with respect to the adjacent first transistor T1 and light-transmitting area LA, the first transistor T1 is located on a side of the first signal sub-line L11 to which the first transistor T1 is electrically connected away from the light-transmitting area LA, and since the structural composition of a transistor is more complex and its fabrication is more difficult than that of a signal line L0, arranging the first transistor T1 adjacent to the light-transmitting area LA on the side of the first signal sub-line L11 to which the first transistor T1 is electrically connected away from the light-transmitting area LA can reduce the influence of the first transistor T1 on the light-transmitting area of the light-transmitting area LA. Furthermore, with respect to the adjacent first transistor T1 and light-transmitting area LA, the driving transistor M0 in the pixel circuit D0 to which the first transistor T1 belongs is located on a side of the first transistor T1 away from the light-transmitting area LA, thereby reducing the influence of the driving transistor M0 and the electrical connection between the driving transistor M0 and the first transistor T1 on the light-transmitting area of the light-transmitting area LA.

When the pixel circuit D0 further includes the driving transistor M0, the second electrode of the first transistor T1 may be electrically connected to the first electrode of the driving transistor M0 through a first connection structure CL1, that is, the first connection structure CL1 is electrically connected between the second electrode of the first transistor T1 and the first electrode of the driving transistor M0. When the first transistor T1 is turned on, a signal transmitted by the first signal line L1 is output to the first connection structure CL1, and the first connection structure CL1 transmits the signal to the first electrode of the driving transistor M0. With respect to the adjacent first transistor T1 and light-transmitting area LA, when the first transistor T1 is located on the side of the first signal sub-line L11 to which the first transistor T1 is electrically connected away from the light-transmitting area LA and the driving transistor M0 in the pixel circuit D0 to which the first transistor T1 belongs is located on the side of the first transistor T1 away from the light-transmitting area LA, the first connection structure CL1 is also located on the side of the first signal sub-line L11 away from the light-transmitting area LA, thereby reducing the influence of the connection structure between the driving transistor M0 and the first transistor T1 on the light-transmitting area of the light-transmitting area LA.

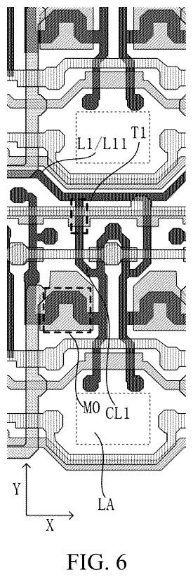

FIG. 6 is a partial structural schematic diagram of a display panel according to an embodiment of the present application.

In an embodiment of the present application, as shown in FIG. 6, the first connection structure CL1, the second electrode of the first transistor T1, and the first electrode of the driving transistor M0 are located in a semiconductor layer and are formed as an integral structure. Therefore, the first connection structure CL1, the second electrode of the first transistor T1, and the first electrode of the driving transistor M0 are respectively different parts in the same semiconductor layer, and the first connection structure CL1 may be located between the second electrode of the first transistor T1 and the first electrode of the driving transistor M0. In this embodiment, although both the first transistor T1 and the driving transistor M0 are relatively close to the light-transmitting area LA, the electrical connection between the first transistor T1 and the driving transistor M0 is implemented without a via hole, thereby avoiding the light-transmitting area of the light-transmitting area LA being affected by such via holes.

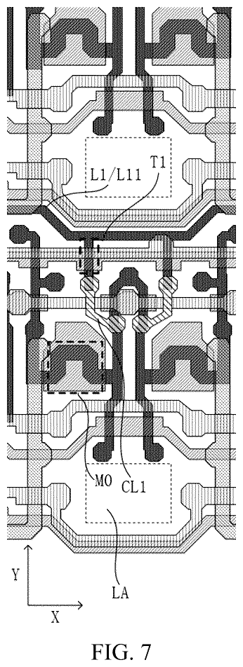

FIG. 7 is a partial structural schematic diagram of a display panel according to an embodiment of the present application.

In an embodiment of the present application, as shown in FIG. 7, the first connection structure CL1 is located in a metal film layer, and the first connection structure CL1 is electrically connected to the second electrode of the first transistor T1 and the first electrode of the driving transistor M0 respectively through different via holes. Since the second electrode of the first transistor T1 and the first electrode of the driving transistor M0 are located in the semiconductor layer, one end of the first connection structure CL1 located in the metal film layer is electrically connected to the second electrode of the first transistor T1 through one via hole, and the other end of the first connection structure CL1 is electrically connected to the first electrode of the driving transistor M0 through another via hole. In this embodiment, the first connection structure CL1 made of metal can more effectively transmit a signal output by the first transistor T1 to the first electrode of the driving transistor M0, for example, when the first transistor T1 is the bias transistor M3, the first connection structure CL1 more effectively transmits a bias voltage to the driving transistor M0 to bias the driving transistor M0.

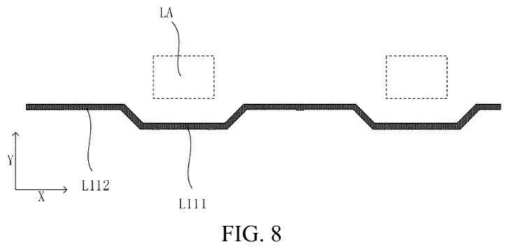

FIG. 8 is a partial structural schematic diagram of a display panel according to an embodiment of the present application.

In an embodiment of the present application, as shown in FIG. 8, the first signal sub-line L11 includes a first portion L111 and a second portion L112. For the first portion L111 and the second portion L112 included in a same first signal sub-line L11, the first portion L111 overlaps with the light-transmitting area LA in the first direction Y and the second portion L112 does not overlap with the light-transmitting area LA in the first direction Y. Herein, the light-transmitting area LA overlaps with and is adjacent to the first portion L111 in the first direction Y. For the convenience of description, the light-transmitting area LA and the first portion L111 are referred to as the adjacent light-transmitting area LA and first portion L111.

In this embodiment, along the first direction Y, the first portion L111 is bent in a direction away from the light-transmitting area LA relative to the second portion L112, that is, with respect to the adjacent light-transmitting area LA and first portion L111, the first portion L111 is bent in the direction away from the light-transmitting area LA relative to the second portion L112 in the same first signal sub-line L11. The first signal sub-line L11 is in the shape of a polyline extending generally along the second direction X, where the portion of the first signal sub-line L11 that overlaps with the light-transmitting area LA in the first direction Y is bent in the direction away from the light-transmitting area LA, which can be regarded as an avoidance design of the first signal sub-line L11 for the light-transmitting area LA, thereby enabling the light-transmitting area LA to have a relatively large light-transmitting area.

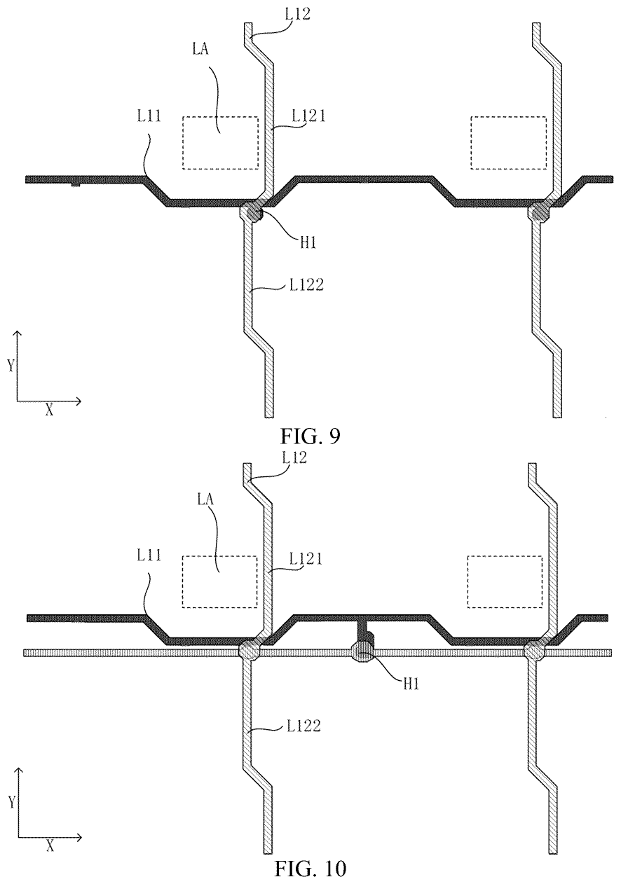

FIG. 9 is a partial structural schematic diagram of a display panel according to an embodiment of the present application.

In an embodiment of the present application, as shown in FIG. 9, the first signal line L1 further includes a second signal sub-line L12 extending along the first direction Y and electrically connected to the first signal sub-line L11, and the second signal sub-line L12 is located in a metal film layer. Therefore, the first signal sub-line L11 located in the semiconductor film layer and the second signal sub-line L12 located in the metal film layer are crossed and electrically connected to form a grid-shaped structure, which reduces the impedance of the first signal line L1 and can effectively reduce the signal loss transmitted on the first signal line L1.

In one technical solution, as shown in FIG. 9, the first signal sub-line L11 and the second signal sub-line L12 are electrically connected through the first via hole H1, and the light-transmitting area LA is located on the side of the first signal sub-line L11 away from the first via hole H1 in the first direction Y. Then, with respect to the adjacent first transistor T1 and light-transmitting area LA, the first via hole H1 between the first signal sub-line L11 to which the first transistor T1 is electrically connected and the second signal sub-line L12, and the light-transmitting area LA are located on both sides of the first signal sub-line L11, thereby avoiding the problem that the first via hole H1 occupies the area of the light-transmitting area LA.

FIG. 10 is a partial structural schematic diagram of a display panel according to an embodiment of the present application.

In one technical solution, as shown in FIG. 10, the first signal sub-line L11 and the second signal sub-line L12 are electrically connected through a first via hole H1, the first via hole H1 does not overlap with the light-transmitting area LA in the first direction Y, and the first via hole H1 does not overlap with the light-transmitting area LA in the second direction X. Therefore, with respect to the adjacent first transistor T1 and light-transmitting area LA, the first via hole H1 between the first signal sub-line L11 to which the first transistor T1 is connected and the second signal sub-line L12 adopts an avoidance design for the light-transmitting area LA in the first direction Y and the second direction X, thereby reducing the structural design difficulty near the position of the light-transmitting area LA.

In an embodiment of the present application, as shown in FIG. 10, the light-transmitting area LA is adjacent to the second signal sub-line L12 in the second direction X, and the second signal sub-line L12 includes a third portion L121 and a fourth portion L122. For the third portion L121 and the fourth portion L122 included in a same second signal sub-line L12, the third portion L121 overlaps with the light-transmitting area LA in the second direction X, and the fourth portion L122 does not overlap with the light-transmitting area LA in the second direction X. Therefore, in the second signal sub-line L12 adjacent to the light-transmitting area LA in the second direction X, the position of the third portion L121 can be regarded as a boundary extending along the first direction Y in the light-transmitting area LA. Herein, the light-transmitting area LA overlaps with and is adjacent to the third portion L121 in the second direction X. For the convenience of description, the light-transmitting area LA and the third portion L121 are referred to as the adjacent light-transmitting area LA and third portion L121.

In this embodiment, along the second direction X, the third portion L121 is bent in a direction away from the light-transmitting area LA relative to the fourth portion L122, that is, with respect to the adjacent light-transmitting area LA and third portion L121, the third portion L121 is bent in a direction away from the light-transmitting area LA relative to the fourth portion L122 in a same second signal sub-line L12. The second signal sub-line L12 is in the shape of a polyline extending generally along the first direction Y, where the portion of the second signal sub-line L12 that overlaps with the light-transmitting area LA in the second direction X is bent in the direction away from the light-transmitting area LA, which can be regarded as the second signal sub-line L12 adopting an avoidance design for the light-transmitting area LA, thereby enabling the light-transmitting area LA to have a larger light-transmitting area.

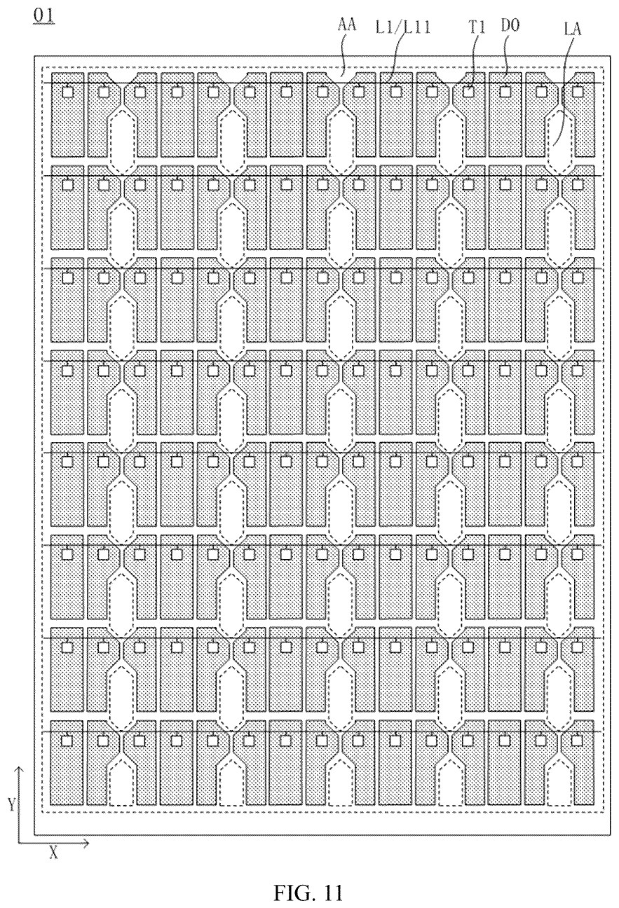

FIG. 11 is a partial structural schematic diagram of a display panel according to an embodiment of the present application.

In an embodiment of the present application, as shown in FIG. 11, the first electrodes of the first transistors T1 arranged along the second direction X are all connected to a same first signal sub-line L11, that is, the first transistors T1 at various positions in the display panel 01 are all electrically connected to the first signal sub-lines L11 located in the semiconductor layer. Therefore, the first signal sub-lines L11 located in the semiconductor layer are relatively uniformly distributed in the display area AA of the display panel 01. When the first signal line L1 further includes a second signal sub-line L12 intersecting the first signal sub-line L11 and electrically connected to the first signal sub-line L11, the grid-shaped structure formed by the intersection and electrical connection of the first signal sub-line L11 and the second signal sub-line L12 can be relatively uniformly distributed in the display area AA of the display panel 01. On one hand, the impedance relatively uniformity of the first signal line L1 at different positions is better; on the other hand, the manufacturing process is relatively simple.

In this embodiment, the light-transmitting areas LA can be uniformly distributed in the display area AA of the display panel 01, and correspondingly, the first signal sub-lines L11 adjacent to the light-transmitting areas LA are also uniformly distributed in the display area AA of the display panel 01.

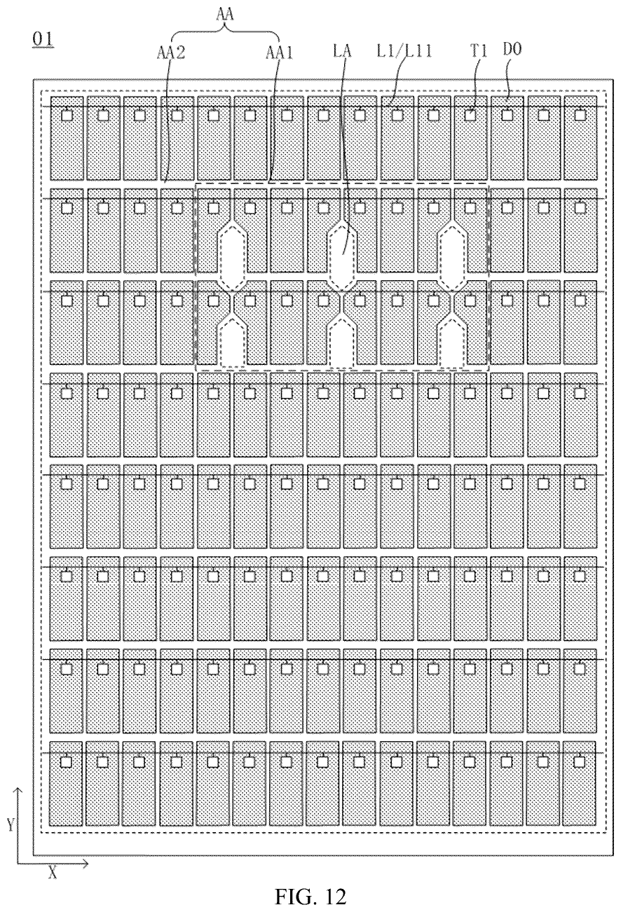

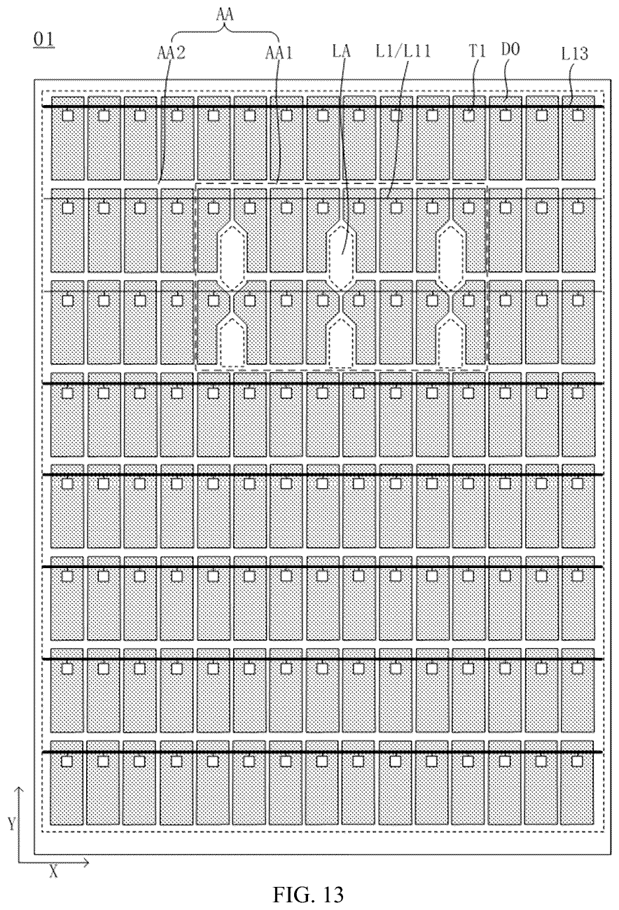

FIG. 12 is a partial structural schematic diagram of a display panel according to an embodiment of the present application, and FIG. 13 is a partial structural schematic diagram of a display panel according to an embodiment of the present application.

In an embodiment of the present application, as shown in FIGS. 12 and 13, the display area AA of the display panel 01 includes a first display area AA1 and a second display area AA2, and the plurality of light-transmitting areas LA are located in the first display area AA1, that is, the light-transmitting areas LA are relatively concentratedly provided in a partial area of the display area AA of the display panel 01.

As shown in FIG. 12, when the light-transmitting areas LA are concentratedly provided in the first display area AA1, the first signal sub-lines L11 can still be uniformly distributed in the display area AA of the display panel 01, and the first electrodes of the first transistors T1 arranged along the first direction Y are all connected to a same first signal sub-line L11.

As shown in FIG. 13, at least a part of the first signal sub-line L11 is located in the first display area AA1, that is, the first signal sub-line L11 passes through the first display area AA1. Moreover, the first signal sub-line L11 is electrically connected at least to the first electrodes of the first transistors T1 in the first display area AA1. For example, as shown in FIG. 13, the first signal sub-line L11 is electrically connected to the first electrodes of the first transistors T1 in the first display area AA1, and is also electrically connected to the first electrodes of the first transistors T1 located on both sides of the first display area AA1 in the second direction X.

When at least a part of the first signal sub-line L11 is located in the first display area AA1, the first signal line L1 further includes a third signal sub-line L13 extending along the second direction X, and the third signal sub-line L13 is located in the second display area AA2. The third signal sub-line L13 is electrically connected to the first electrodes of the first transistors T1 in the second display area AA2, and the third signal sub-line L13 is located in a metal film layer. Therefore, the first electrodes of at least a part of the first transistors T1 located in the second display area AA2 are electrically connected to the third signal sub-line L13 made of metal.

Herein, a plurality of third signal sub-lines L13 intersect and are electrically connected to a plurality of second signal sub-lines L12 to form a grid-shaped structure. Specifically, the part of the grid-shaped first signal line L1 located in the first display area AA1 is a grid-shaped structure formed by the first signal sub-lines L11 made of semiconductor and the second signal sub-lines L12 made of metal, and at least a part of the grid-shaped first signal line L1 located in the second display area AA2 is a grid-shaped structure formed by the third signal sub-lines L13 made of metal and the second signal sub-lines L12 made of metal.

In an embodiment of the present application, as shown in FIG. 5, the pixel circuit D0 includes a second transistor T2, and the second transistor T2 overlaps with the first transistor T1 in the second direction X. Herein, with respect to the adjacent first transistor T1 and light-transmitting area LA, the first transistor T1 is one of the transistors in the pixel circuit D0 where it is located that is adjacent to the light-transmitting area LA, and therefore, the second transistor T2 adjacent to the first transistor T1 is also relatively close to the light-transmitting area LA. In addition, the second transistor T2 may have no overlap with the light-transmitting area LA in the second direction X, for example, as shown in FIG. 13, the first transistor T1 is located below the light-transmitting area LA, and the second transistor T2 is located at the lower left of the light-transmitting area LA.

A first electrode of the second transistor T2 is electrically connected to a second signal line L2, and when the second transistor T2 is turned on, a signal transmitted on the second signal line L2 can be written to a corresponding node. The second signal line L2 includes at least a fourth signal sub-line L21 extending along the second direction X, the fourth signal sub-line L21 is electrically connected to the first electrode of the second transistor T2, where the fourth signal sub-line L21 is electrically connected to a plurality of second transistors T2 arranged along the second direction X, that is, the fourth signal sub-line L21 is electrically connected to the plurality of second transistors T2 in its extending direction.

In a feasible implementation, a second electrode of the second transistor T2 is electrically connected to an output terminal of the pixel circuit D0, and the second transistor T2 is configured to control the transmission of a reset voltage transmitted on the second signal line L2 to the output terminal of the pixel circuit D0. Then, the second transistor T2 may be the second reset transistor M7, the second signal line L2 is the reset signal line REF. Therefore, the second transistor T2 is configured to transmit the reset voltage transmitted on the reset signal line REF to the output terminal of the pixel circuit D0, that is, to the light-emitting device LD, so as to reset one electrode of the light-emitting device LD that is electrically connected to the pixel circuit D0.

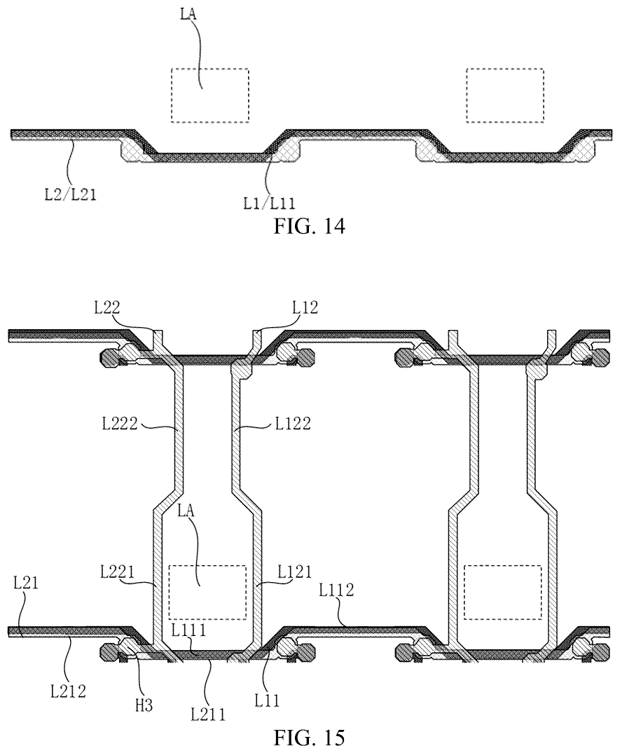

FIG. 14 is a partial structural schematic diagram of a display panel according to an embodiment of the present application.

It should be noted that the fourth signal sub-line L21 is not necessarily a straight-line structure, for example, as shown in FIG. 14, the fourth signal sub-line L21 is a polyline structure, and the fourth signal sub-line L21 extending along the second direction X refers to the extending direction of the fourth signal sub-line L21 being generally the second direction X, that is, the overall extending direction of the fourth signal sub-line L21 is the second direction X. As shown in FIG. 14, the fourth signal sub-line L21 includes a fifth portion L211 and a sixth portion L212. Of the fifth portion L211 and the sixth portion L212 included in a same fourth signal sub-line L21, the fifth portion L211 overlaps with the light-transmitting area LA in the first direction Y, and the sixth portion L212 does not overlap with the light-transmitting area LA in the first direction Y. Herein, the light-transmitting area LA overlaps with and is adjacent to the fifth portion L211 in the first direction Y. For the convenience of description, the light-transmitting area LA and the fifth portion L211 are referred to as the adjacent light-transmitting areas LA and fifth portions L211.

In this embodiment, as shown in FIG. 14, along the first direction Y, the fifth portion L211 is bent in a direction away from the light-transmitting area LA relative to the sixth portion L212, that is, with respect to the adjacent light-transmitting area LA and fifth portion L211, the fifth portion L211 is bent in a direction away from the light-transmitting area LA relative to the sixth portion L212 in a same fourth signal sub-line L21. The fourth signal sub-line L21 is in the shape of a polyline extending generally along the second direction X, where the part of the fourth signal sub-line L21 that overlaps with the light-transmitting area LA in the first direction Y is bent in a direction away from the light-transmitting area LA, which can be regarded as the fourth signal sub-line L21 adopting an avoidance design for the light-transmitting area LA, thereby enabling the light-transmitting area LA to have a larger light-transmitting area.

Herein, as shown in FIG. 5, the fourth signal sub-line L21 is electrically connected to the first electrode of the second transistor T2 through a second via hole H2. Since the second transistor T2 may have no overlap with the light-transmitting area LA in the first direction Y, the design of the second via hole H2 corresponding to the first electrode of the second transistor T2 has a relatively small impact on the area of the light-transmitting area LA; therefore, the fourth signal sub-line L21 and the first electrode of the second transistor T2 can be electrically connected through the second via hole H2.

In one technical solution, as shown in FIGS. 5 and 14, the light-transmitting area LA is located on a side of the fourth signal sub-line L21 away from the second via hole H2, that is, the light-transmitting area LA and the second via hole H2 are located on both sides of the fourth signal sub-line L21, so as to avoid the second via hole H2 occupying the area of the light-transmitting area LA as much as possible.

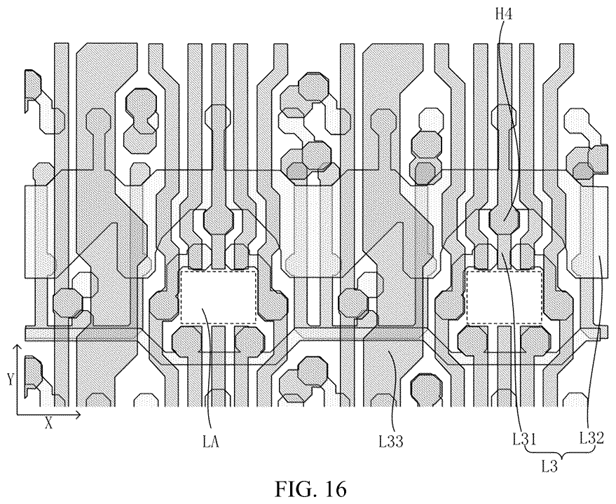

FIG. 15 is a partial structural schematic diagram of a display panel according to an embodiment of the present application.

In an embodiment of the present application, as shown in FIG. 15, the second signal line L2 further includes a fifth signal sub-line L22 extending along the first direction Y and electrically connected to the fourth signal sub-line L21. Then, a plurality of fourth signal sub-lines L21 and a plurality of fifth signal sub-lines L22 cross and are electrically connected to form a grid-shaped structure, which reduces the impedance of the second signal line L2 and can effectively reduce the signal loss transmitted on the second signal line L2.

Herein, as shown in FIG. 15, the fifth signal sub-line L22 and the fourth signal sub-line L21 can be electrically connected through a third via hole H3, and the light-transmitting area LA is located on a side of the fourth signal sub-line L21 away from the third via hole H3 and on a side of the fifth signal sub-line L22 away from the third via hole H3.

In an embodiment of the present application, as shown in FIG. 15, the light-transmitting area LA is adjacent to the fifth signal sub-line L22 in the second direction X, and the fifth signal sub-line L22 includes a seventh portion L221 and an eighth portion L222. For the seventh portion L221 and the eighth portion L222 included in a same fifth signal sub-line L22, the seventh portion L221 overlaps with the light-transmitting area LA in the second direction X, and the eighth portion L222 does not overlap with the light-transmitting area LA in the second direction X. Therefore, in the fifth signal sub-line L22 adjacent to the light-transmitting area LA in the second direction X, the position of the seventh portion L221 can be regarded as a boundary extending along the first direction Y in the light-transmitting area LA. Herein, the light-transmitting area LA overlaps with and is adjacent to the seventh portion L221 in the second direction X. For the convenience of description, the light-transmitting area LA and the seventh portion L221 are referred to as the adjacent light-transmitting area LA and seventh portion L221.

In this embodiment, along the second direction X, the seventh portion L221 is bent in a direction away from the light-transmitting area LA relative to the eighth portion L222, that is, with respect to the adjacent light-transmitting area LA and seventh portion L221, the seventh portion L221 is bent in a direction away from the light-transmitting area LA relative to the eighth portion L222 in a same fifth signal sub-line L22. The fifth signal sub-line L22 is in the shape of a polyline extending generally along the first direction Y, where the part of the fifth signal sub-line L22 that overlaps with the light-transmitting area LA in the second direction X is bent in a direction away from the light-transmitting area LA, which can be regarded as the fifth signal sub-line L22 adopting an avoidance design for the light-transmitting area LA, thereby enabling the light-transmitting area LA to have a larger light-transmitting area.

In an embodiment of the present application, as shown in FIG. 5 and FIG. 15, the pixel circuit D0 includes a first transistor T1 and a second transistor T2, a first electrode of the first transistor T1 is electrically connected to a first signal line L1, and a first electrode of the second transistor T2 is electrically connected to a second signal line L2. The first signal line L1 includes a first signal sub-line L11 extending along the second direction X, and the second signal line L2 includes a fourth signal sub-line L21 extending along the second direction X; the second direction X intersects the first direction Y; the first signal sub-line L11 and the first electrode of the first transistor T1 are located in a same semiconductor layer, and the fourth signal sub-line L21 is located in a metal film layer. For the first portion L111 and the second portion L112 included in a same first signal sub-line L11, the first portion L111 overlaps with the light-transmitting area LA in the first direction Y, and the second portion L112 does not overlap with the light-transmitting area LA in the first direction Y; for a fifth portion L211 and a sixth portion L212 included in a same fourth signal sub-line L21, the fifth portion L211 overlaps with the light-transmitting area LA in the first direction Y, and the sixth portion L212 does not overlap with the light-transmitting area LA in the first direction Y.

Herein, the first portion L111 at least partially overlaps with the fifth portion L211 in the direction perpendicular to the plane of the display panel 01. Therefore, the portions of the first signal sub-line L11 and the second signal sub-line L12 that respectively overlap with the light-transmitting area LA in the first direction Y and are relatively close to each other overlap in the direction perpendicular to the plane of the display panel 01, which reduces the space occupied in the first direction Y by the portions of the first signal sub-line L11 and the second signal sub-line L12 that respectively overlap with the light-transmitting area LA in the first direction Y, thereby being conducive to increasing the width of the light-transmitting area LA in the first direction Y, and further being conducive to increasing the area of the light-transmitting area LA.

In this embodiment, along the first direction Y, the first portion L111 may be bent in a direction away from the light-transmitting area LA relative to the second portion L112, and the fifth portion L211 may be bent in a direction away from the light-transmitting area LA relative to the sixth portion L212.

Furthermore, the second portion L112 at least partially overlaps with the sixth portion L212 in the direction perpendicular to the plane of the display panel 01, that is, at least portions of the first signal sub-line L11 and the second signal sub-line L12 that do not overlap with the light-transmitting area LA in the first direction Y may also overlap in the direction perpendicular to the plane of the display panel 01. Therefore, the first signal sub-line L11 and the second signal sub-line L12 overlap substantially in the direction perpendicular to the plane of the display panel 01, thereby being capable of reducing the wiring difficulty of the display panel 01.

In an embodiment of the present application, as shown in FIG. 15, the first signal line L1 further includes a second signal sub-line L12 extending along the first direction Y and electrically connected to the first signal sub-line L11, and the second signal line L2 further includes a fifth signal sub-line L22 extending along the first direction Y and electrically connected to the fourth signal sub-line L21. The second signal sub-line L12 includes a third portion L121, and the third portion L121 overlaps with the light-transmitting area LA in the second direction X; and the fifth signal sub-line L22 includes a seventh portion L221, and the seventh portion L221 overlaps with the light-transmitting area LA in the second direction X. Herein, the light-transmitting area LA is adjacent to the second signal sub-line L12 and the fifth signal sub-line L22 in the second direction X, that is, the light-transmitting area LA is adjacent to the third portion L121 and the seventh portion L221 respectively in the second direction X; for the third portion L121 and the seventh portion L221 adjacent to the light-transmitting area LA, along the second direction X, the third portion L121 and the seventh portion L221 are located on two opposite sides of the light-transmitting area LA.

Herein, the third portion L121 and the seventh portion L221 may be located in a same metal film layer. Since both the third portion L121 and the seventh portion L221 are adjacent to the light-transmitting area LA, and the third portion L121 and the seventh portion L221 are located on two opposite sides of the light-transmitting area LA, the third portion L121 and the seventh portion L221 being located in a same metal film layer can provide a better collimating effect on the light passing through the light-transmitting area LA.

In a feasible implementation, the second signal sub-line L12 and the fourth signal sub-line L21 may be located in a same metal film layer, thereby being capable of reducing the wiring difficulty of the display panel 01.

FIG. 16 is a partial structural schematic diagram of a display panel according to an embodiment of the present application.

In an embodiment of the present application, as shown in FIG. 16, the display panel 01 includes a third signal line L3, the third signal line L3 includes at least a sixth signal sub-line L31 extending along the first direction Y and a seventh signal sub-line L32 extending along the second direction X, and the sixth signal sub-line L31 is electrically connected to the seventh signal sub-line L32 through a fourth via hole H4. The electrical connection between the sixth signal sub-line L31 and the seventh signal sub-line L32 extending in different directions can reduce the impedance on the third signal line L3.

The sixth signal sub-line L31 and the fourth via hole H4 are both located between adjacent light-transmitting areas LA along the first direction Y, that is, the sixth signal sub-line L31 overlaps with the light-transmitting area LA in the first direction Y and terminates before extending to the light-transmitting area LA, and the fourth via hole H4 for electrically connecting the sixth signal sub-line L31 to the seventh signal sub-line L32 is also provided to avoid the light-transmitting area LA. Therefore, the arrangement of the sixth signal sub-line L31 electrically connected to the seventh signal sub-line L32 not only reduces the impedance of the third signal line L3 but also does not affect the light-transmitting area of the light-transmitting area LA.

In an embodiment of the present application, as shown in FIG. 16, the third signal line L3 further includes an eighth signal sub-line L33 extending along the first direction Y, and the eighth signal sub-line L33 is electrically connected to the seventh signal sub-line L32 through a via hole. The eighth signal sub-line L33 does not overlap with the light-transmitting area LA in the direction perpendicular to the plane of the display panel 01, and the eighth signal sub-line L33 overlaps with a plurality of light-transmitting areas LA and a plurality of sixth signal sub-lines L31 in the second direction X. Then, the eighth signal sub-line L33 may avoid the light-transmitting area LA and extend along the first direction Y and penetrate through the display area AA.

In an embodiment of the present application, with reference to FIGS. 5 and 16, the pixel circuit D0 includes a driving transistor M0 and a third transistor T3, a first electrode of the third transistor T3 is electrically connected to the seventh signal sub-line L32 through a fifth via hole H5, a second electrode of the third transistor T3 is electrically connected to the driving transistor M0, and the third transistor T3 is configured to control the transmission of a power supply voltage transmitted on the third signal line L3 to the driving transistor M0. Therefore, the third transistor T3 may be the power supply voltage writing transistor M4 and the third signal line L3 may be the power supply voltage line PVDD, and in this case, the third signal line L3 includes signal sub-lines L0 extending along different directions and electrically connected to each other, which can as much as possible make the magnitude of the power supply voltage transmitted on the third signal line L3 substantially the same at different positions, thereby ensuring the display uniformity of the display panel 01.

Herein, the fifth via hole H5 does not overlap with the light-transmitting area LA in the direction perpendicular to the plane of the display panel 01, that is, the fifth via hole for electrically connecting the third transistor T3 to the third signal line L3 also adopts an avoidance design for the light-transmitting area LA, thereby enabling the light-transmitting area LA to have a larger light-transmitting area.

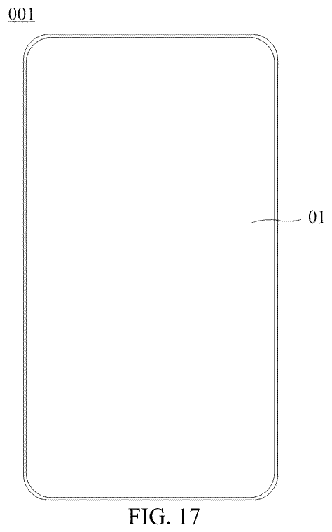

FIG. 17 is a schematic diagram of a display apparatus according to an embodiment of the present application.

As shown in FIG. 17, an embodiment of the present application further provides a display apparatus 001 including the display panel 01 provided by any of the above embodiments. Of course, the display apparatus 001 shown in FIG. 17 is merely illustrative, and the display apparatus 001 may be any electronic device having a display function, such as a mobile phone, a tablet computer, a notebook computer, an electronic paper book, a television, and a splicing display apparatus.

The above are merely preferred embodiments of the present application and are not intended to limit the present application. Any modifications, equivalent substitutions, improvements, and the like made within the spirit and principle of the present application shall fall within the protection scope of the present application.

What is claimed is:

1. A display panel, comprising:
a plurality of sub-pixels;
a plurality of light-transmitting areas;
a plurality of signal lines; and
a plurality of pixel circuits, wherein
the light-transmitting areas do not overlap with the signal lines and the pixel circuits in a direction perpendicular to a plane of the display panel;
the display panel further comprises a first display column and a second display column arranged along a second direction, the first display column comprises first color sub-pixels sequentially arranged along a first direction, the second display column comprises pixel units sequentially arranged along the first direction, and a respective pixel unit comprises a second color sub-pixel and a third color sub-pixel arranged along the first direction; along the second direction, the pixel units overlap with the first color sub-pixels; and the second direction intersects the first direction; and
a respective light-transmitting area is located between adjacent first color sub-pixels along the first direction and/or a respective light-transmitting area is located between adjacent second color sub-pixel and third color sub-pixel along the first direction.

2. The display panel according to claim 1, wherein a respective pixel circuit comprises a first transistor, and a first electrode of the first transistor is electrically connected to a first signal line; and a corresponding light-transmitting area is located on a side of the first transistor in the first direction; and
wherein the first signal line comprises a first signal sub-line extending along the second direction; and the first signal sub-line is connected to first electrodes of a plurality of first transistors arranged along the second direction, and the first signal sub-line and the first electrodes of the first transistors are located in a same semiconductor layer and are formed as an integral structure.

3. The display panel according to claim 2, wherein the pixel circuit further comprises a driving transistor, a second electrode of the first transistor is electrically connected to a first electrode of the driving transistor through a first connection structure, and the first connection structure, the second electrode of the first transistor, and the first electrode of the driving transistor are located in the semiconductor layer and are formed as an integral structure.

4. The display panel according to claim 2, wherein the pixel circuit further comprises a driving transistor, a second electrode of the first transistor is electrically connected to a first electrode of the driving transistor through a first connection structure, the first connection structure is electrically connected to the second electrode of the first transistor and the first electrode of the driving transistor respectively through different via holes, and the first connection structure is located in a metal film layer.

5. The display panel according to claim 2, wherein the first signal sub-line comprises a first portion and a second portion; and
for the first portion and the second portion comprised in a same first signal sub-line, the first portion overlaps with the light-transmitting area in the first direction and the second portion does not overlap with the light-transmitting area in the first direction, and along the first direction, the first portion is bent in a direction away from the light-transmitting area relative to the second portion.

6. The display panel according to claim 2, wherein the first signal line further comprises a second signal sub-line extending along the first direction and electrically connected to the first signal sub-line, and the second signal sub-line is located in a metal film layer.

7. The display panel according to claim 6, wherein the first signal sub-line and the second signal sub-line are electrically connected through a first via hole, and the light-transmitting area is located on a side of the first signal sub-line away from the first via hole in the first direction.

8. The display panel according to claim 6, wherein the first signal sub-line and the second signal sub-line are electrically connected through a first via hole, the first via hole does not overlap with the light-transmitting area in the first direction, and the first via hole does not overlap with the light-transmitting area in the second direction.

9. The display panel according to claim 6, wherein the light-transmitting area is adjacent to the second signal sub-line in the second direction, and the second signal sub-line comprises a third portion and a fourth portion; and
for the third portion and the fourth portion comprised in a same second signal sub-line, the third portion overlaps with the light-transmitting area in the second direction, and the fourth portion does not overlap with the light-transmitting area in the second direction; and along the second direction, the third portion is bent in a direction away from the light-transmitting area relative to the fourth portion.

10. The display panel according to claim 2, wherein the first electrodes of the first transistors arranged along the second direction are all connected to a same first signal sub-line.

11. The display panel according to claim 2, wherein a display area of the display panel comprises a first display area and a second display area, and the plurality of light-transmitting areas are located in the first display area;
the first signal line further comprises a third signal sub-line extending along the second direction, and the third signal sub-line is located in a metal film layer; at least a part of the first signal sub-line is located in the first display area and the third signal sub-line is located in the second display area; and
the first signal sub-line is electrically connected at least to the first electrodes of the first transistors in the first display area, and the third signal sub-line is electrically connected to the first electrodes of the first transistors in the second display area.

12. The display panel according to claim 2, wherein the pixel circuit further comprises a driving transistor, a second electrode of the first transistor is electrically connected to the driving transistor, and the first transistor is configured to control the transmission of a bias voltage transmitted on the first signal line to the driving transistor.

13. The display panel according to claim 2, wherein the pixel circuit comprises a second transistor, the second transistor overlaps with the first transistor in the second direction, and a first electrode of the second transistor is electrically connected to a second signal line; and the second signal line comprises at least a fourth signal sub-line extending along the second direction, and the fourth signal sub-line is electrically connected to the first electrode of the second transistor through a second via hole; and
the fourth signal sub-line comprises a fifth portion and a sixth portion, for the fifth portion and the sixth portion comprised in a same fourth signal sub-line, the fifth portion overlaps with the light-transmitting area in the first direction and the sixth portion does not overlap with the light-transmitting area in the first direction, and along the first direction, the fifth portion is bent in a direction away from the light-transmitting area relative to the sixth portion.

14. The display panel according to claim 13, wherein the light-transmitting area is located on a side of the fourth signal sub-line away from the second via hole.

15. The display panel according to claim 13, wherein the second signal line further comprises a fifth signal sub-line extending along the first direction and electrically connected to the fourth signal sub-line, and the fifth signal sub-line is electrically connected to the fourth signal sub-line through a third via hole; and
the light-transmitting area is located on a side of the fourth signal sub-line away from the third via hole and on a side of the fifth signal sub-line away from the third via hole.

16. The display panel according to claim 15, wherein the light-transmitting area is adjacent to the fifth signal sub-line in the second direction, and the fifth signal sub-line comprises a seventh portion and an eighth portion; and
for the seventh portion and the eighth portion comprised in a same fifth signal sub-line, the seventh portion overlaps with the light-transmitting area in the second direction and the eighth portion does not overlap with the light-transmitting area in the second direction, and along the second direction, the seventh portion is bent in a direction away from the light-transmitting area relative to the eighth portion.

17. The display panel according to claim 13, wherein a second electrode of the second transistor is electrically connected to an output terminal of the pixel circuit; and the second transistor is configured to control the transmission of a reset voltage transmitted on the second signal line to the output terminal of the pixel circuit.

18. The display panel according to claim 1, wherein the pixel circuit comprises a first transistor and a second transistor, a first electrode of the first transistor is electrically connected to a first signal line, and a first electrode of the second transistor is electrically connected to a second signal line;
the first signal line comprises a first signal sub-line extending along the second direction, and the second signal line comprises a fourth signal sub-line extending along the second direction; the first signal sub-line and the first electrode of the first transistor are located in a same semiconductor layer, and a second signal sub-line is located in a metal film layer;
for a first portion and a second portion comprised in a same first signal sub-line, the first portion overlaps with the light-transmitting area in the first direction and the second portion does not overlap with the light-transmitting area in the first direction, and along the first direction, the first portion is bent in a direction away from the light-transmitting area relative to the second portion; and
for a fifth portion and a sixth portion comprised in a same fourth signal sub-line, the fifth portion overlaps with the light-transmitting area in the first direction and the sixth portion does not overlap with the light-transmitting area in the first direction, and along the first direction, the fifth portion is bent in a direction away from the light-transmitting area relative to the sixth portion;
the first portion at least partially overlaps with the fifth portion in the direction perpendicular to the plane of the display panel.

19. The display panel according to claim 18, wherein the second portion at least partially overlaps with the sixth portion in the direction perpendicular to the plane of the display panel.

20. The display panel according to claim 18, wherein the first signal line further comprises a second signal sub-line extending along the first direction and electrically connected to the first signal sub-line, and the second signal line further comprises a fifth signal sub-line extending along the first direction and electrically connected to the fourth signal sub-line; and
the light-transmitting area is adjacent to the second signal sub-line in the second direction, the second signal sub-line comprises a third portion, and the third portion overlaps with the light-transmitting area in the second direction; the light-transmitting area is adjacent to the fifth signal sub-line in the second direction, the fifth signal sub-line comprises a seventh portion, and the seventh portion overlaps with the light-transmitting area in the second direction;
for the third portion and the seventh portion that are adjacent to the light-transmitting area, along the second direction, the third portion and the seventh portion are located on two opposite sides of the light-transmitting area.

21. The display panel according to claim 20, wherein the third portion and the seventh portion are located in a same metal film layer.

22. The display panel according to claim 1, wherein the display panel comprises a third signal line, the third signal line comprises at least a sixth signal sub-line extending along the first direction and a seventh signal sub-line extending along the second direction, and the sixth signal sub-line is electrically connected to the seventh signal sub-line through a fourth via hole; and
the sixth signal sub-line and the fourth via hole are both located between adjacent light-transmitting areas along the first direction.

23. The display panel according to claim 22, wherein the third signal line further comprises an eighth signal sub-line extending along the first direction, and the eighth signal sub-line is electrically connected to the seventh signal sub-line through a via hole; and
the eighth signal sub-line does not overlap with the light-transmitting area in the direction perpendicular to the plane of the display panel, and the eighth signal sub-line overlaps with a plurality of light-transmitting areas and a plurality of sixth signal sub-lines in the second direction.

24. The display panel according to claim 22, wherein the pixel circuit comprises a driving transistor and a third transistor, a first electrode of the third transistor is electrically connected to the seventh signal sub-line through a fifth via hole, a second electrode of the third transistor is electrically connected to the driving transistor, and the third transistor is configured to control the transmission of a power supply voltage transmitted on the third signal line to the driving transistor; and
the fifth via hole does not overlap with the light-transmitting area in the direction perpendicular to the plane of the display panel.

25. A display apparatus, comprising a display panel, wherein the display panel comprises:
a plurality of sub-pixels;
a plurality of light-transmitting areas;
a plurality of signal lines; and
a plurality of pixel circuits, wherein
the light-transmitting areas do not overlap with the signal lines and the pixel circuits in a direction perpendicular to a plane of the display panel;
the display panel further comprises a first display column and a second display column arranged along a second direction, the first display column comprises first color sub-pixels sequentially arranged along a first direction, the second display column comprises pixel units sequentially arranged along the first direction, and a respective pixel unit comprises a second color sub-pixel and a third color sub-pixel arranged along the first direction; along the second direction, the pixel units overlap with the first color sub-pixels; and the second direction intersects the first direction; and
a respective light-transmitting area is located between adjacent first color sub-pixels along the first direction and/or a respective light-transmitting area is located between adjacent second color sub-pixel and third color sub-pixel along the first direction.
